(19) United States
(12) Patent Application Publication
(10) Pub. No.: US 2020/0184901 A1
(43) Pub. Date: Jun. 11, 2020

(54) FLEXIBLE DISPLAY PANEL

(71) Applicant: Wuhan China Star Optoelectronics Semiconductor Display Technology Co., LTD, Wuhan, Hubei (CN)

(72) Inventor: Guang LI, Wuhan, Hubei (CN)

(21) Appl. No.: 16/091,058

(22) PCT Filed: Sep. 12, 2018
(86) PCT No.: PCT/CN2018/105331

§ 371 Date: Oct. 3, 2018

(30) Foreign Application Priority Data
Mar. 12, 2018 (CN) 201810200897.0

(51) Int. Cl. G09G 3/3291; H01L 51/00

(52) U.S. Cl. CPC G09G 3/3291; H01L 2251/5338; H01L 51/0097

(57) ABSTRACT

The flexible display panel includes an active area (AA), an outer lead bonding (OLB) area, and a number of driver chips working cooperatively in fulfilling the complete driving function to the AA. The AA and the OLB area are formed on a same flexible organic substrate. The multiple driver chips are disposed in the OLB area adjacent to the AA. The driver chips are arranged in a pattern as required. The flexible display panel of the present invention obviates the problem of driver IC limiting the bending of the flexible display panel, while fulfilling the display function and to a greater degree achieving the bending capability of the flexible display panel.

### CROSS-REFERENCE TO RELATED APPLICATIONS

This application is a national phase entry of PCT Patent Application No. PCT/CN2018/105331, filed on Sep. 12, 2018, which claims priority to Chinese Patent Application No. 201810200897.0, filed on Mar. 12, 2018, both of which are hereby incorporated herein by reference in their entireties.

### BACKGROUND OF THE INVENTION

### (a) Technical Field of the Invention

The present invention is generally related to display technologies, and more particular to a flexible display panel.

### (b) Description of the Prior Art

Organic light emitting diode (OLED) displays are gaining popularity and competitiveness in recent years due to their wide color gamut, high contrast, using solid-state elements, etc. Especially the use of solid-state elements provides great advantage for OLED displays in achieving flexible displays. On the other hand, displays are employed in various new applications, and flexible displays have become the focus of development.

The key in achieving flexibility is to maintain circuit and element functionality after they are bent. Using a flexible material such as organic or oxide semiconductor is a feasible approach. Another approach is to use flexible medium and metallic material.

For a display to be flexible, not only the active area (AA) of the display has to be flexible, also the outer lead bonding (OLB) area has to be flexible as well. Currently, the substrate for the AA and OLB areas of a flexible display is a flexible organic substrate of thickness between a dozen microns and a few tens microns basically made of polyimide (PI). If chip on PI (COP) bonding is used in the OLB area, and as the driver IC is a rectangular and rigid silicon element, the flexibility of the OLB area, and therefor of the entire display, would be significantly limited.

FIG. 1 is a structural schematic diagram showing a conventional flexible display panel found on existing products such as Samsung S7 edge. As illustrated, the conventional flexible display panel includes an AA 1, an OLB area 2, an external circuit 3, and a driver IC 4 for driving the AA 1. The AA 1 and the OLB 2 are formed on a same flexible organic substrate so that both of them are flexible. The driver IC 4 is disposed by COP on the OLB area 2 adjacent to the AA 1. The external circuit 3 is bonded to the OLB area 2 for transmitting external signals, and may be implemented on a flexible printed circuit (FPC) board. Existing driver IC 4 is connected to, and drives, data lines and scan lines in the AA 1. The driver IC 4 may vary in size, depending on its function and resolution, but, basically, the driver IC 4 is disposed parallel with the adjacent edge of the AA 1 at a distance about a few millimeters. As such, the magnitude and scale of bending of the flexible display panel is limited by the dimension of the driver IC 4. The flexible display panel cannot be bended in the direction of the driver IC 4's long edges. Usually, as such, only the border region of the flexible display panel is bendable, significantly constraining the applicability of the flexible display panel.

### SUMMARY OF THE INVENTION

Therefore, an objective of the present invention is to provide a flexible display panel resolving the problem of driver IC limiting the bending capability of the flexible display panel.

To achieve the objective, the flexible display panel includes an active area (AA), an outer lead bonding (OLB) area, and a number of driver chips working cooperatively in fulfilling a driving function to the AA. The AA and the OLB area are formed on a same flexible organic substrate. The driver chips are disposed in the OLB area adjacent to the AA, and the driver chips are arranged in a pattern in the OLB area.

The driver chips are bonded to the OLB area using chip on PI (COP) or chip on film (COF) bonding.

The driver chips are arranged in the OLB area at intervals.

Each driver chip functions independently, or has to function cooperatively with another driver chip.

Each driver chip is a chip integrating multiple functions.

The driver chips are disposed in the OLB area to match impedance of data lines of the AA.

The driver chips are aligned in a column in the OLB area relative to and parallel with an adjacent edge of the AA.

The driver chips are disposed in two columns in the OLB area relative to and parallel with an adjacent edge of the AA. The chips in the two columns alternate vertically.

The driver chips are disposed in a curve in the OLB area relative to an adjacent edge of the AA.

The flexible display panel further includes an external circuit bonding to the OLB area.

To achieve the objective, another flexible display panel of the present invention includes an AA, an OLB area, and a number of driver chips working cooperatively in fulfilling a driving function to the AA. The AA and the OLB area are formed on a same flexible organic substrate. The driver chips are disposed in the OLB area adjacent to the AA, and the driver chips are arranged in a pattern in the OLB area.

The driver chips are bonded to the OLB area using COP or COF bonding.

Each driver chip functions independently, or has to function cooperatively with another driver chip, or is a chip integrating multiple functions.

The flexible display panel further includes an external circuit bonding to the OLB area.

As such, the flexible display panel of the present invention obviates the problem of driver IC limiting the bending of the flexible display panel, while fulfilling the display function and to a greater degree achieving the bending capability of the flexible display panel.

The foregoing objectives and summary provide only a brief introduction to the present invention. To fully appreciate these and other objects of the present invention as well as the invention itself all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort.

FIG. 1 is a structural schematic diagram showing a conventional flexible display panel.

FIG. 2 is a structural diagram showing a flexible display panel according to a first embodiment of the present invention.

FIG. 3 is a structural diagram showing a flexible display panel according to a second embodiment of the present invention.

FIG. 4 is a structural diagram showing a flexible display panel according to a third embodiment of the present invention.

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

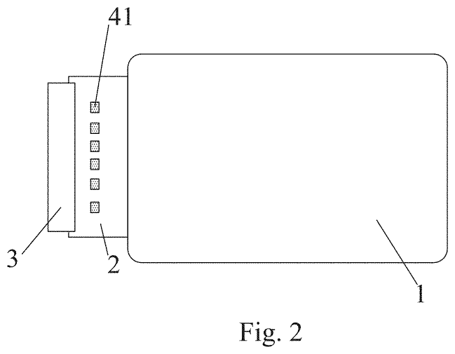

FIG. 2 is a structural diagram showing a flexible display panel according to a first embodiment of the present invention. As illustrated, the present embodiment includes an active area (AA) 1, an outer lead bonding (OLB) area 2, an external circuit 3 disposed in the OLB area 2 for transmitting external signals, and a number of driver chips 41 working cooperatively in fulfilling the complete driving function to the AA 1. The AA 1 and the OLB area 2 are formed on a same flexible organic substrate made of, for example, polyimide (PI) so that both the AA 1 and the OLB 2 are flexible. The multiple driver chips 41 are disposed in the OLB area 2 adjacent to the AA 1 by chip on PI (COP) bonding. The driver chips 41 may be arranged in various patterns in the OLB area 2. As shown in FIG. 2, the driver chips 41 are aligned in a column relative to and parallel with an adjacent edge of the AA 1. In contrast to the prior art that employs a single driver IC, the present invention have multiple driver chips 41 that work cooperatively together to fulfill the driving function. As the driver chips 41 are much smaller than the conventional single driver IC, the present embodiment allows bending in the column's direction, thereby achieving almost perfect, fully bendable flexible display panel.

In the present embodiment, the COP bonding is applied to dispose the driver chips 41 in the OLB area 2. In alternative embodiments, chip on film (COF) or other method may be employed.

The present embodiment employs multiple chips of smaller dimensions to replace and cooperatively perform the same function as the single driver IC of the prior art. As such, the present embodiment obviates the problem of driver IC limiting the bending of the flexible display panel, while fulfilling the same display function and to a greater degree achieving the bending capability of the flexible display panel.

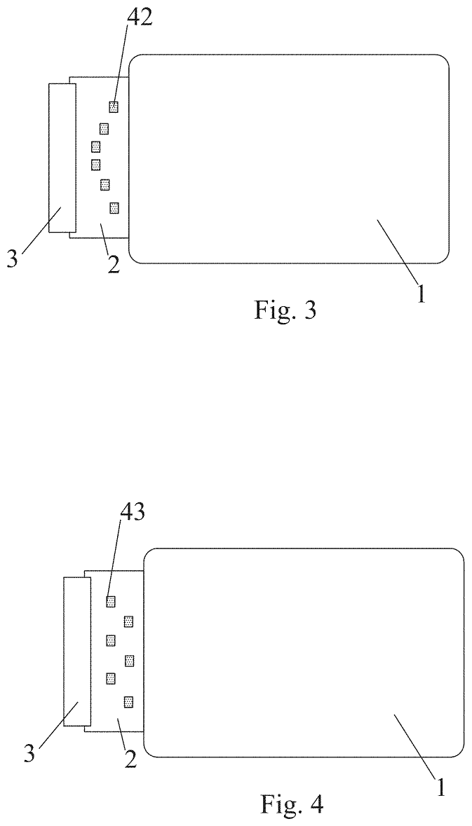

FIG. 3 is a structural diagram showing a flexible display panel according to a second embodiment of the present invention. As illustrated, the present embodiment includes an AA 1, an OLB area 2, an external circuit 3 disposed in the OLB area 2, and a number of driver chips 42 working cooperatively in fulfilling the complete driving function to the AA 1. The multiple driver chips 42 are disposed in the OLB area 2 in a curve relative to an adjacent edge of the AA 1. The locations of the chips 42 are selected so as to match the impedance of the data lines of the AA 1.

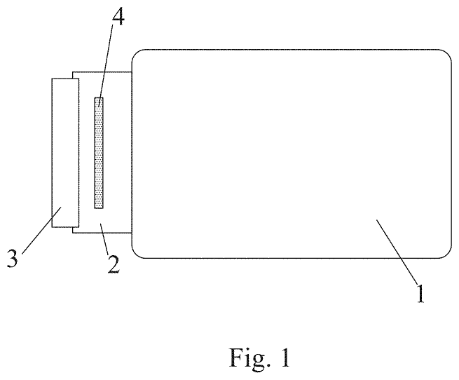

The multiple driver chips are disposed in the OLB area at intervals. These smaller chips may be placed as required with a specific distance in between so as to achieve flexible bending. There is no limitation on the chip distance. The advantages of the distributed driver chips include superior flexibility and, more importantly, better impedance matching due to the separation of function and flexible layout. As shown in FIG. 1, different driver chips 42 are at difference distances from the AA 1, thereby more accurately matching the impedance of the data lines. The impedance difference among the data lines is reduced, and the display quality is more uniform.

FIG. 4 is a structural diagram showing a flexible display panel according to a third embodiment of the present invention. As illustrated, the present embodiment includes an AA 1, an OLB area 2, an external circuit 3 disposed in the OLB area 2, and a number of driver chips 43 working cooperatively in fulfilling the complete driving function to the AA 1. The multiple driver chips 43 are disposed in the OLB area in two columns relative to and parallel with an adjacent edge of the AA 1, and the chips 42 in the two columns alternate vertically.

The arrangement of the multiple driver chips is not limited to a regular pattern, and they may be arranged at will.

The present invention breaks up a single driver IC into multiple chips of smaller dimensions. Each smaller chip may have complete function or has to work with another smaller chip or integrate multiple functions. In other words, each driver chip may function independently, or has to function cooperatively with another driver chip, or is a chip integrating multiple functions. Currently, a driver IC includes gate driver on array (GOA) and data driving functions. A more powerful driver IC may further include touch control function. The smaller driver chips may include even more functions such as GOA, data driving, touch control, power IC, demura, IR drop compensation, sub-pixel rendering (SPR), high bandwidth memory (HBM), high dynamic range (HDR), and a combination of these functions. In other words, the present invention may break up the complete function of an existing driver IC, or may include additional function not available in existing driver IC such as power IC (currently power IC and driver IC are separate ICs). The present invention may achieve the power IC function through multiple smaller chips.

In summary, the flexible display panel of the present invention obviates the problem of driver IC limiting the bending of the flexible display panel, while fulfilling the display function and to a greater degree achieving the bending capability of the flexible display panel.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the claims of the present invention.

I claim:

1. A flexible display panel, comprising an active area (AA), an outer lead bonding (OLB) area, and a plurality of driver chips working cooperatively in fulfilling a driving function to the AA; wherein
the AA and the OLB area are formed on a same flexible organic substrate;
the driver chips are disposed in the OLB area adjacent to the AA; and
the driver chips are arranged in a pattern in the OLB area.

2. The flexible display panel according to claim 1, wherein the driver chips are bonded to the OLB area using chip on PI (COP) or chip on film (COF) bonding.

3. The flexible display panel according to claim 1, wherein the driver chips are arranged in the OLB area at intervals.

4. The flexible display panel according to claim 1, wherein each driver chip functions independently, or has to function cooperatively with another driver chip.

5. The flexible display panel according to claim 1, wherein each driver chip is a chip integrating multiple functions.

6. The flexible display panel according to claim 1, wherein the driver chips are disposed in the OLB area to match impedance of data lines of the AA.

7. The flexible display panel according to claim 1, wherein the driver chips are aligned in a column in the OLB area relative to and parallel with an adjacent edge of the AA.

8. The flexible display panel according to claim 1, wherein the driver chips are disposed in two columns in the OLB area relative to and parallel with an adjacent edge of the AA; and the chips in the two columns alternate vertically.

9. The flexible display panel according to claim 1, wherein the driver chips are disposed in a curve in the OLB area relative to an adjacent edge of the AA.

10. The flexible display panel according to claim 1, further comprising an external circuit bonding to the OLB area.

11. The flexible display panel, comprising an AA, an OLB area, an external circuit; and a plurality of driver chips working cooperatively in fulfilling a driving function to the AA; wherein
the AA and the OLB area are formed on a same flexible organic substrate;
the driver chips are disposed in the OLB area adjacent to the AA;
the driver chips are arranged in a pattern in the OLB area;
the driver chips are bonded to the OLB area using COP or COF bonding;
each driver chip functions independently, or has to function cooperatively with another driver chip, or is a chip integrating multiple functions; and
the external circuit is bonded to the OLB area.

12. The flexible display panel according to claim 11, wherein the driver chips are arranged in the OLB area at intervals.

13. The flexible display panel according to claim 11, wherein the driver chips are disposed in the OLB area to match impedance of data lines of the AA.

14. The flexible display panel according to claim 11, wherein the driver chips are aligned in a column in the OLB area relative to and parallel with an adjacent edge of the AA.

15. The flexible display panel according to claim 11, wherein the driver chips are disposed in two columns in the OLB area relative to and parallel with an adjacent edge of the AA; and the chips in the two columns alternate vertically.

16. The flexible display panel according to claim 11, wherein the driver chips are disposed in a curve in the OLB area relative to an adjacent edge of the AA.
